(19) United States
(12) Patent Application Publication
(10) Pub. No.: US 2025/0218907 A1
(43) Pub. Date: Jul. 3, 2025

(54) LEADFRAME WITH RETAINING FEATURES

(71) Applicant: TEXAS INSTRUMENTS INCORPORATED, DALLAS, TX (US)

(72) Inventors: Jefferson LUGUE, BAGUIO CITY (PH); ZuoHui CHEN, CHENGDU (CN)

(21) Appl. No.: 18/398,969

(22) Filed: Dec. 28, 2023

(51) Int. Cl. H01L 23/495; H01L 23/00; H01L 25/065

(52) U.S. Cl. CPC H01L 23/49548; H01L 23/4952; H01L 23/49575; H01L 24/32; H01L 24/48; H01L 25/0657; H01L 2224/32145; H01L 2224/32245; H01L 2224/48145; H01L 2224/48247; H01L 2225/06524; H01L 2924/01029; H01L 2924/182

(57) ABSTRACT

A semiconductor package that includes a leadframe having retaining features adapted to receive a molding compound is provided. As one example, an IC package includes a leadframe of a conductive material including a die attach pad and a lead finger separated from an edge of the die attach pad. The leadframe has a first surface and a second surface opposite the first surface. The IC package also includes retaining features on the lead finger at the second surface. The IC package further includes a die on the first surface at the die attach pad. The IC package yet further includes a molding compound that encapsulates the leadframe and the die and extends into and/or around the retaining features.

### TECHNICAL FIELD

This description relates to semiconductor packages having a lead frame with retaining features that are adapted to receive molding compound.

### BACKGROUND

Due to the trend toward miniaturization of electronic products, such as mobile phones, tablets, digital cameras, and the like, there has been a trend in semiconductor package manufacturing towards smaller and more densely packed semiconductor structures and semiconductor layers. Generally, semiconductor packages are built on a leadframe formed from a conductive material. The leadframe carries signals from the die to the semiconductor package or to different chips, used in a dual in-line package (DIP), quad flat package (QFP), and other semiconductor packages.

### SUMMARY

A first example is related to an integrated circuit (IC) package. The IC package includes a leadframe of a conductive material including a die attach pad and a lead finger separated from an edge of the die attach pad. The leadframe has a first surface and a second surface opposite the first surface. The IC package also includes retaining features on the lead finger at the second surface. The IC package further includes a die on the first surface at the die attach pad. The IC package yet further includes a molding compound that encapsulates the leadframe and the die and extends into and/or around the retaining features.

A second example is related to a method of forming an integrated circuit (IC). The method includes providing a leadframe of a conductive material including a lead finger and a die attach pad separated by a distance. The leadframe has a first surface and a second surface opposite the first surface. The method also includes forming retaining features in the second surface of the leadframe at the lead finger that are adapted to receive molding compound. The retaining features are formed by adding and/or removing material with respect to the second surface.

A third example is related to a device. The device includes a sheet of a conductive material having a first surface and a second surface opposite the first surface. Fabrication features extend in a first direction along at least one of the first and second surfaces. The sheet includes a die attach pad and a plurality of lead fingers. The plurality of lead fingers are spaced apart from and surrounding the die attach pad. An arrangement of retaining features are formed in at least one lead finger of the lead fingers extending along a second direction that is approximately perpendicular to the first direction.

### BRIEF DESCRIPTION OF THE DRAWINGS

FIG. 1 illustrates an example of a semiconductor device ready for packaging.

FIG. 2A illustrates an example of V-shaped retaining features at a lead finger of the semiconductor device.

FIG. 2B illustrates an example of U-shaped retaining features at a lead finger of the semiconductor device.

FIG. 2C illustrates an example of through retaining features at a lead finger of the semiconductor device.

FIG. 2D illustrates examples of a V-shaped retaining feature and a protruding retaining feature at a lead finger of the semiconductor device.

FIG. 3 is a flowchart illustrating an example method for forming semiconductor package including a leadframe having retaining features.

FIG. 4 illustrates an example of a conductive sheet for forming the semiconductor package including the leadframe having the retaining features.

FIG. 5 illustrates an example of a first part of the method of FIG. 3.

FIG. 6 illustrates an example of a second part of the method of FIG. 3.

FIG. 7 illustrates an example of a third part of the method of FIG. 3.

FIG. 8 illustrates an example of a fourth part of the method of FIG. 3.

FIG. 9 illustrates an example of a fifth part of the method of FIG. 3.

FIG. 10 illustrates an example of a sixth part of the method of FIG. 3.

### DETAILED DESCRIPTION

This description relates to forming retaining features at a surface of a leadframe to help reduce delamination of molding compound of a packaged semiconductor device. The retaining features are adapted to receive or otherwise interlock with the molding compound and provide additional surface area for improving adhesion of the molding compound to the leadframe. The retaining features may be arranged amongst the fabrication features on the surface of the leadframe. For example, the retaining features are arranged to extend in a direction transverse relative to a direction of the fabrication feature to increase the mechanical interlocking force. As described herein, the retaining features can be formed with various shapes and sizes to increase adhesion by providing a mechanical interlocking structure for molding compound applied to form to the semiconductor package.

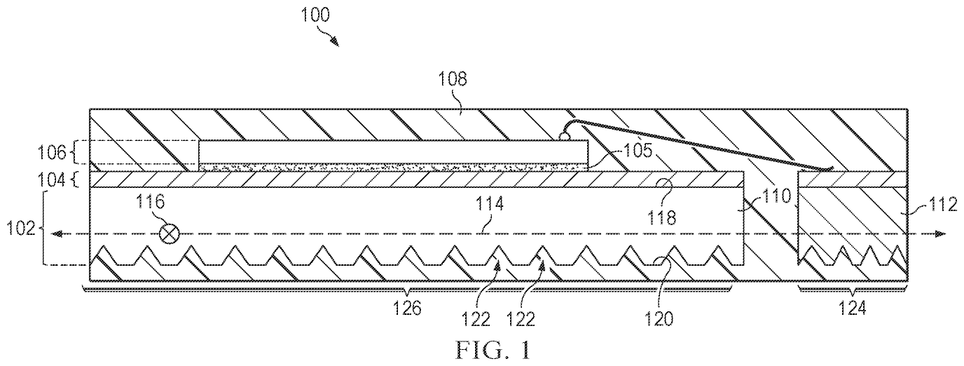

FIG. 1 illustrates an example of a semiconductor device 100 ready for packaging. The semiconductor device 100 includes a leadframe 102 formed of an electrically conductive material, such as copper, palladium, gold, silver, or other appropriate conductive metal or metal alloy with similar properties. For example, the leadframe 102 is formed from a copper sheet. A bond layer 105 bonds a die 106 to a die-attach portion of a metal contact layer 104 of the leadframe 102. The bond layer 105 is, for example, a layer of an adhesive agent, such as an epoxy resin. The leadframe 102, the bond layer 105, and the die 106 are at least partially encapsulated in a molding compound 108 to form a packaged semiconductor device 100, such as an integrated circuit (IC) or a system on chip (SOC). The molding compound 108 is formed of one or more insulating material, such as organic resins (e.g., epoxy), inorganic resins, and/or other suitable materials.

The leadframe 102 defines a plane extending through the leadframe 102. In some examples, the leadframe 102 includes a die attach pad 110 spaced apart from one or more lead fingers 112. For example, a plurality of lead fingers 112 can be disposed around (e.g., circumscribe) the die attach pad 110. The die attach pad 110 provides an electrical connection between the die 106 and the lead finger 112. During packaging, the semiconductor device 100 is singulated such that the lead finger 112 forms a lead exposed to an external environment. The leads of the singulated semiconductor device 100 enable the die 106 to be electrically coupled with one or more other electrical components external to the semiconductor device 100.

The lead finger 112 is separated from an edge of the die attach pad 110 by a distance in a first direction 114 and coplanar with the plane of the leadframe 102. Although shown with one lead finger 112 in FIG. 1 for clarity, a plurality of lead fingers are spaced apart from and surround the die attach pad 110. Lead fingers of the plurality of lead fingers are also separated from one another in one or more directions coplanar with the plane of the leadframe 102. For example, a given lead finger 112 is separated from other lead fingers in the first direction 114 and the lead fingers 112 extend in a second direction 116 (e.g., shown into the page) that is coplanar with and approximately perpendicular to the first direction 114. The distance between the lead finger 112 and the edge of the die attach pad 110 and/or other lead fingers of the plurality of lead fingers are based on the shape of the lead finger 112. As one example, the lead finger 112 has a perimeter that defines a shape of the lead finger 112. The shape of the lead finger 112 can be rectangular, chamfered rectangular, T-shaped, L-shaped, E-shaped, U-shaped, and circular, among other shapes.

The leadframe 102, and therefore the die attach pad 110 and the lead finger 112, have a first surface 118 and an opposing second surface 120. A metal contact layer 104 is formed on the first surface 118 of the die attach pad 110 of the leadframe 102. The metal contact layer 104 can extend to the periphery of the die attach pad 110 and the lead finger 112. The metal contact layer 104 may additionally or alternatively include an oxidation layer or laminate layer.

An arrangement of retaining features 122 is formed on the leadframe 102 at the second surface 120. The arrangement of retaining features 122 are configured to provide structure that the molding compound can bond with to increase adhesion therebetween and reduce delamination of the molding compound from the lead frame, particularly at the lead fingers 112. As described herein, the retaining features can have different shapes and/or sizes. In the example of FIG. 1, the leadframe 102 has a leadframe thickness between the first surface 118 and the second surface 120. The retaining features 122 extend a depth from the second surface 120 towards the first surface 118 that is less than or equal to approximately 40% of the leadframe thickness. In some examples, the retaining features 122 extend through the leadframe 102 from an opening in the second surface 120 to an opening in the first surface 118. The arrangement of retaining features 122 forms an array of retaining features. The spacing between adjacent pairs of the retaining features in a set of retaining features can be approximately 25-40 microns.

The retaining features 122 may be formed in sets. For example, a set of retaining features includes at least one retaining feature. While the retaining features 122 are shown as an array of retaining features in FIG. 1, the retaining features 122 may include a single retaining feature. For example, the retaining features 122 may include a single retaining feature that is a groove extending the length of the lead finger 112.

Because the lead finger 112 is separated from the die attach pad 110 by a distance and is exposed to the external environment during singulation, the lead finger 112 is more prone to delamination. Accordingly, in one example, the retaining features 122 are formed as a first set of retaining features 124 at the second surface 120 of the lead finger 112, but the retaining features 122 are not formed at the second surface 120 of the die attach pad 110. Alternatively, or additionally, the retaining features 122 are formed as the first set of retaining features 124 and a second set of retaining features 126. The second set of retaining features is formed on at least a portion of the second surface 120 of the die attach pad 110. In some examples, the second set of retaining features 126 is formed in the second surface 120 even if the first set of retaining features 124 is not formed. Whether a first set of retaining features 124, a second set of retaining features 126, or both are formed is based on the application of the semiconductor device 100, the location of fabrication features at the second surface 120 of the leadframe 102, type of the molding compound 108, and/or the formation techniques used to form the retaining features 122.

The retaining features 122 are formed to be adapted to receive the molding compound 108 and increase the surface area of the second surface 120. The additional surface area provides increased adhesion between the leadframe 102 and the molding compound 108. Additionally, the arrangement of fabrication features that may be formed on the second surface 120 tend to contribute to delamination. For example, a fabrication feature positioned at an edge of the lead finger 112 causes a seam at the interface between the leadframe 102 and the molding compound 108. The seam creates an increased likelihood of delamination. Accordingly, the fabrication features extend in the first direction 114, and the retaining features include spaced apart grooves that extend longitudinally along the lead finger 112 at the second surface 120 in the second direction 116 (e.g., shown extending into the page) approximately perpendicular to the first direction 114 of the fabrication features. In one example, the retaining features 122 are formed to extend in the second direction 116 and positioned amongst the fabrication features. The perpendicular placement of the retaining features 122 relative to the fabrication features provides a mechanical interlocking force that reduces delamination. Consequently, the retaining features 122 reduce the number of failures caused by delamination and increase production yield.

The placement of the fabrication features in the first direction 114 and the retaining features in the second direction 116 is an example of the perpendicular relative placement of the fabrication features and the retaining features 122. The fabrication features and the retaining features 122 may be formed in any approximately perpendicular arrangement with respect to the fabrication features at the second surface 120. As described herein, the retaining features are not limited to being arranged approximately perpendicular to the fabrication features, and can be formed with nearly any arrangement at the second surface 120 configured to promote adhesion with the molding compound.

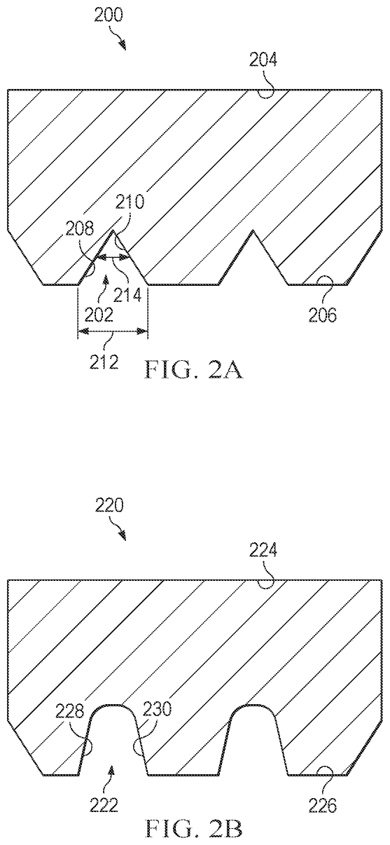

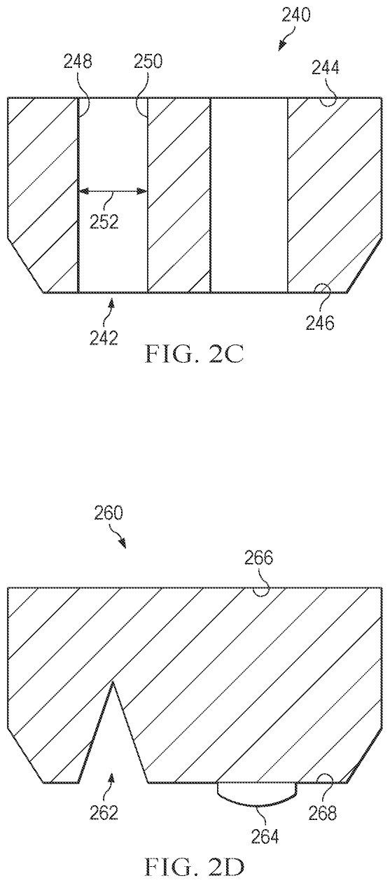

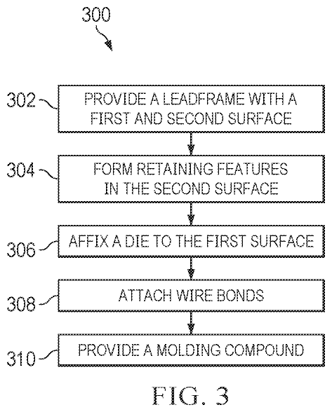

As shown in FIGS. 2A-2D, the retaining features have various cross-sectional shapes. Turning to FIG. 2A, a lead finger 200 (e.g., the lead finger 112 of FIG. 1) has a retaining feature 202 (e.g., the retaining features 122 of FIG. 1) with a cross-sectional V-shape. The lead finger 200 has a first surface 204 (e.g., the first surface 118 of FIG. 1) and a second surface 206 (e.g., the second surface 120 of FIG. 1) opposite the first surface 204. The retaining feature 202 has a first sidewall 208 and a second sidewall 210. The first sidewall 208 and the second sidewall 210 extend from the second surface 206 in a longitudinal direction toward the first surface 204.

Widths of the retaining feature 202, defined in a lateral direction, are defined by the separation between the opposing sidewalls 208 and 210 of respective retaining features. In some examples, the widths of the retaining feature 202 include a first width 212 defined by the distance between sidewalls at second surface 206. For example, the first width 212 is continuous with the second surface 206. A second width 214 is at a first depth from the second surface 206. Accordingly, the first width 212 is proximal the second surface 206 and the second width 214 is distal the second surface 206. In FIG. 2A, the first width 212 is greater than the second width 214.

The opposing sidewalls 208 and 210 are tapered. For example, the first sidewall 208 forms a first angle with the second surface 206 and the second sidewall 210 forms a second angle with the second surface 206. The first angle and the second angle may be the same or different. The first angle and/or the second angle are angles between 30 degrees and 89 degrees. In some examples, the first sidewall 208 and the second sidewall 210 extend toward each other and converge at a point spaced from the second surface 206.

In FIG. 2B, a lead finger 220 (e.g., the lead finger 112 of FIG. 1) has a retaining feature 222 (e.g., the retaining features 122 of FIG. 1) with a cross-sectional U-shape. The lead finger 222 has as first surface 224 (e.g., the first surface 118 of FIG. 1) and a second surface 226 (e.g., the second surface 120 of FIG. 1) opposite the first surface 224. The retaining feature 222 has a first sidewall 228 and a second sidewall 230. Here, the first sidewall 228 and the second sidewall 230 arc and converge along a curved path to form U-shape thereof.

In FIG. 2C, a lead finger 240 (e.g., the lead finger 112 of FIG. 1) has a retaining feature 242 (e.g., the retaining features 122 of FIG. 1) that extends through the lead finger 240. The lead finger 240 has as first surface 244 (e.g., the first surface 118 of FIG. 1) and a second surface 246 (e.g., the second surface 120 of FIG. 1) opposite the first surface 244. The retaining feature 242 has a first sidewall 248 and a second sidewall 250. The first sidewall 248 and the second sidewall 250 extend from the second surface 246 in a longitudinal direction to the first surface 244. The first sidewall 248 and the second sidewall 250 are approximately parallel and have a width 252. In other examples, the sidewalls can be skewed relative to each other, such as narrowing or widening the distance between sidewalls extending from the second surface 246.

As shown in FIG. 2D, a variety of retaining features are used. For example, a lead finger 260 (e.g., the lead finger 112 of FIG. 1) includes a first retaining feature 262 (e.g., the retaining features 122 of FIG. 1) and a second retaining feature 264 (e.g., retaining features 122 of FIG. 1). The lead finger 260 has as first surface 266 (e.g., the first surface 118 of FIG. 1) and a second surface 268 (e.g., the second surface 120 of FIG. 1) opposite the first surface 266. The first retaining feature 262 has a V-shape formed by removing material from lead finger 260 (similar to the retaining feature of FIG. 2A), such as to form notches, recesses, channels, grooves, trenches, holes, slits, slots, indentations, and the like. The second retaining feature 264 protrudes from the second surface 268 formed by adding material to the second surface 268 of the lead finger 260, such as to form bumps, peaks, corrugations, ridges, and the like. Therefore, the retaining features are formed by adding conductive material to the second surface 268 of the leadframe (e.g., the leadframe 102 of FIG. 1) and/or by removing the conductive material from the leadframe.

Furthermore, various cross-sectional shapes are used for the retaining features. The cross-sectional shapes of the retaining features may be based on the application of the semiconductor device (e.g., the semiconductor device 100 of FIG. 1), the location of fabrication features at the second surface 268 of the leadframe, type of the molding compound (e.g., the molding compound 108 of FIG. 1), and/or the formation techniques used to form the retaining features. Examples of some techniques that can be used to form retaining features include rolling, stamping, grinding, cutting, punching, welding, deposition, etching and the like.

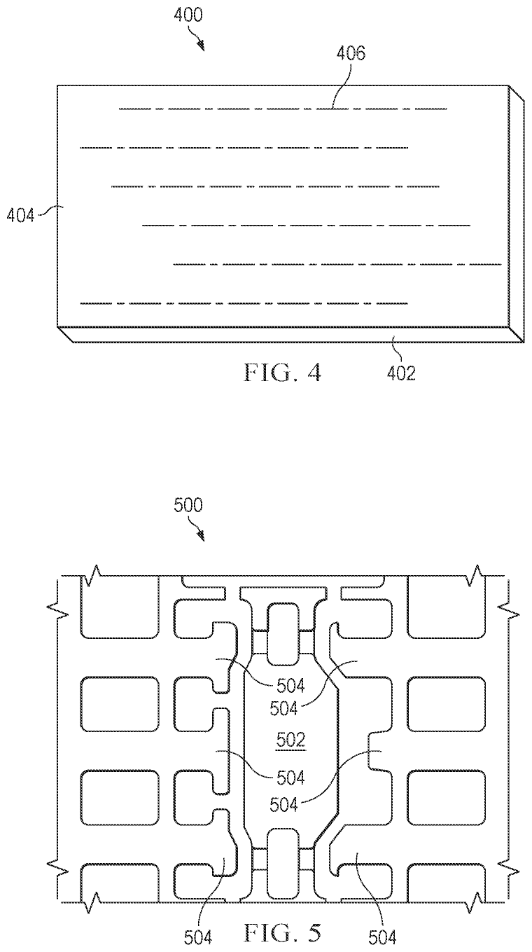

FIG. 3 illustrates a method 300 for formation of the semiconductor device, such as the semiconductor device 100 of FIG. 1 with retaining features. The method of FIG. 3 will be described with respect to FIGS. 4-10, which illustrate examples of the semiconductor device 100 at different stages e fabrication method 300. For purposes of simplification, FIGS. 4-10 employ the same reference numbers to denote the same structure.

At 302, the method 300 includes providing a leadframe (e.g., the leadframe 102 of FIG. 1). The leadframe is formed from a conductive sheet. For example, FIG. 4 illustrates an example conductive sheet 400 formed of a conductive material, such as copper. The conductive sheet 400 includes a first surface 402 (e.g., the first surface 118 of FIG. 1, the first surface 204, 224, 244, and 266 of FIGS. 2A-2D, respectively) and a second surface 404 (e.g., the second surface 120 of FIG. 1, the second surface 206, 226, 246, and 268 of FIGS. 2A-2D, respectively) opposite the first surface 402. The conductive sheet 400 may include fabrication features 406 extending in a first direction on the second surface 404. The fabrication features 406 are an artifact of forming the conductive sheet 400. For example, the fabrication features 406 may be roll marks resulting from rolling out the conductive sheet 400 to a desired thickness. As another example, the fabrication features 406 may be press marks resulting from pressing the conductive sheet 400.

A leadframe 500 (e.g., the leadframe 102 of FIG. 1), shown in FIG. 5, is formed at 302, from the conductive sheet 400. For example, the leadframe 500 is etched from the conductive sheet 400. The etching is performed to form a die attach pad 502 (e.g., the die attach pad 110 of FIG. 1) and a plurality of lead fingers 504 (e.g., the lead finger 112 of FIG. 1) arranged around, coplanar with and spaced apart from a periphery of the die attach pad 502. In some examples, a plurality of leadframes can be formed from the conductive sheet 400. Lead fingers of a plurality of lead fingers 504 have respective surfaces that have a lead finger shape, such as a rectangular shape, a T-shape, or an L-shape.

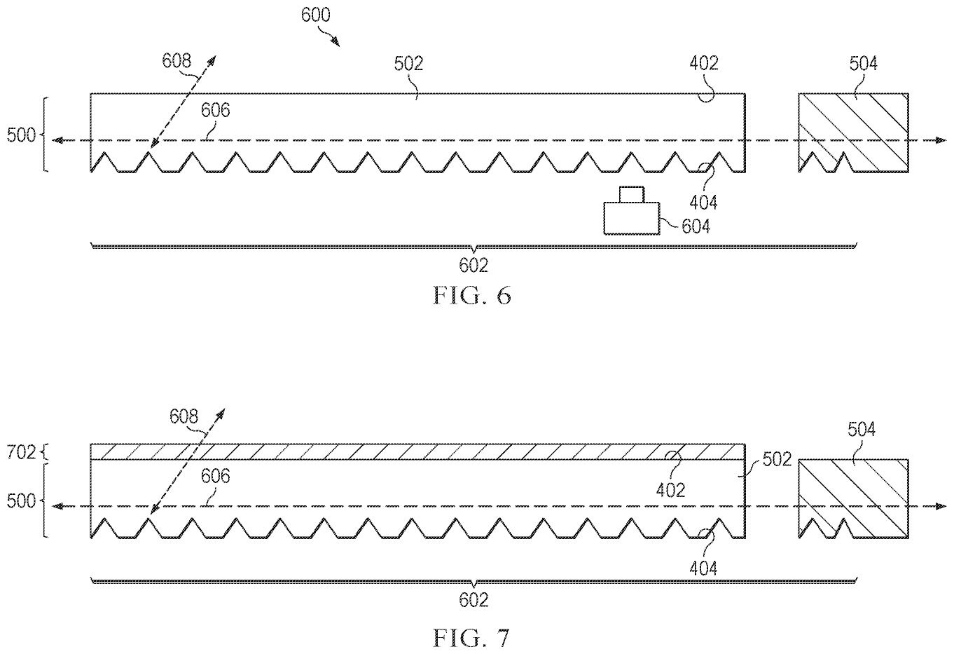

At 304, the method 300 includes forming retaining features in the second surface of the leadframe at the lead finger that are adapted to adhere to molding compound. As shown in the example of FIG. 6, the leadframe 500 has a first surface 402 and a second surface 404 opposite the first surface 402 resulting in an altered leadframe 600. A set of retaining features 602 (e.g., the retaining features 122 of FIG. 1, the retaining feature 202 of FIG. 2A, the retaining feature 222 of FIG. 2B, the retaining feature 242 of FIG. 2C, and the retaining features 262 and 264 of FIG. 2D) are formed in the second surface 404 with a feature tool 604 in a second stage. The feature tool 604 adds and/or removes conductive material to and/or from the second surface 404 of the leadframe 500 to form the retaining features 602. For example, the feature tool 604 is a laser, saw etc. to scribe, saw, etch, deposit conductive material to provide the retaining features 602 at the second surface 404.

As described herein, the retaining features 602 can have a variety of shapes. In some examples, the retaining features 602 are spaced apart voids or recesses that extend a depth from the second surface 404 towards the first surface 402. Accordingly, the retaining features may include voids. The depth of the void of the retaining features 602 can be less than or equal to approximately 40% of a thickness of the leadframe 500. In one example, the retaining features 602 have a cross-sectional V-shape. For example, the V-shaped retaining features 602 has spaced apart sidewalls that are tapered along a direction extending from the second surface 404 towards the first surface 402.

Because fabrication features 406 are present on the second surface 404, the retaining features 602 are arranged amongst the fabrication features 406. In one example, the fabrication features 406 extend in a first direction 606 (e.g., the first direction 114 of FIG. 1). The first direction 606 extends in a direction from the die attach pad 502 to the lead finger 504 in a plane defined by the leadframe 500. The retaining features 602 extend longitudinally along the die attach pad 502 and the lead finger 504 at the second surface 404. The retaining features 602 extend longitudinally in a second direction 608 (e.g., the second direction 116 of FIG. 1), coplanar with and approximately perpendicular to the first direction 606. By adding the retaining features to the lead fingers with the fabrication features, as described herein, the combined features can form interlock structure to inhibit delamination caused by the fabrication features.

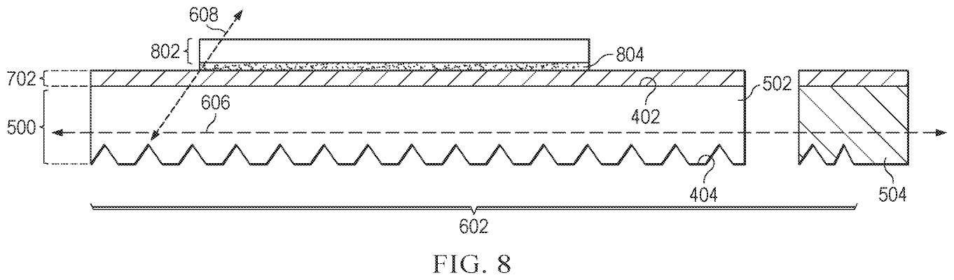

At 306, the method 300 includes affixing a die to the first surface. The die is affixed to the die attach pad 502 with a bond layer. As shown in the example of FIG. 7, a bond layer 804 (e.g., the bond layer 105 of FIG. 1) is applied to at least a metal contact layer 702 (e.g., the metal contact layer 104 of FIG. 1) overlaying the die attach pad 502 in a third stage. Accordingly, the bond layer 804 does not extend past the first surface 402 of the die attach pad 502. The bond layer 804 is an adhesive agent, such as an epoxy resin. FIG. 8 shows a die 802 (e.g., the die 106 of FIG. 1) is affixed to the first surface 402 of the die attach pad 502 via the bond layer 804 in a fourth stage.

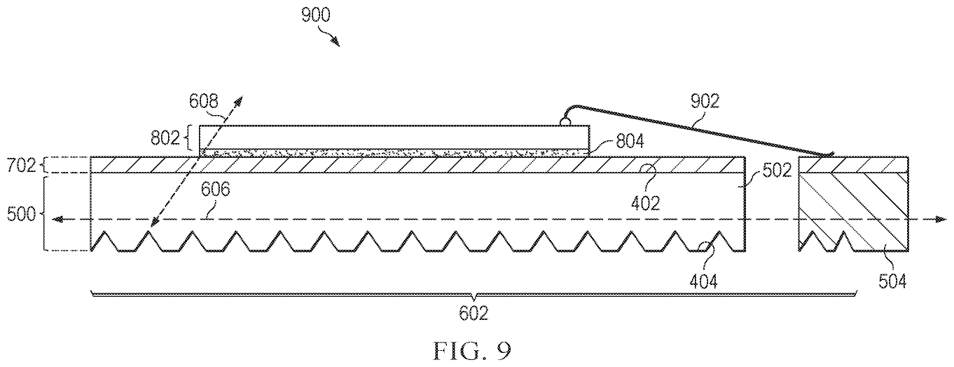

At 308, the method 300 includes attaching bond wires from the die to the lead finger. For example, FIG. 9 shows a bond wire 902 being attached at the die 802 and the lead finger 504, in a fifth stage, resulting in a semiconductor device 900 (e.g., the semiconductor device 100 of FIG. 1). In particular, a top surface of the die 802 includes a first bond pad and the lead finger 504 defines a second bond pad at the first surface 402. The bond wire 902 is coupled between the first and second bond pads. The bond wire 902 forms an electrical connection between the die 802 and the lead finger 504.

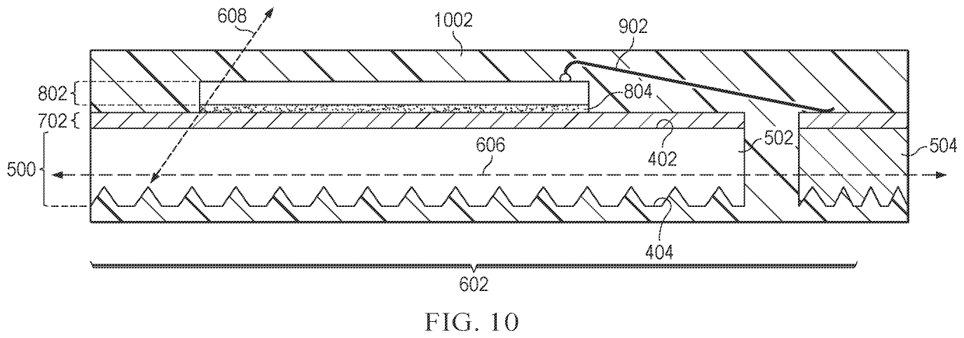

At 310, the method 300 includes providing a molding compound to at least partially encapsulate the semiconductor device. For example, FIG. 10, the semiconductor device 900 encapsulated in a molding compound 1002 (e.g., the molding compound 108 of FIG. 1) in a sixth stage. The molding compound 1002 at least partially encapsulates the die 802 and the second surface 404 of the leadframe 500. In some embodiments, the semiconductor device is a two-mold body device, such as a small outline transistor (SOT) device, with molding compound on the top and bottom of the semiconductor device. The retaining features 602 are adapted to receive the molding compound 1002 to increase the surface area of the second surface 404. The additional surface area provides additional adhesion. Furthermore, the retaining features 602 may be configured and arranged to extend in a perpendicular direction relative to a direction of the fabrication feature to increase the mechanical interlocking force with the molding compound. The increased mechanical interlocking between the leadframe 500 and the molding compound 1002 reduces delamination and the failures caused by delamination.

In this description, unless otherwise stated, “about,” “approximately” or “substantially” preceding a parameter means being within +/−10 percent of that parameter. Modifications are possible in the described embodiments, and other embodiments are possible, within the scope of the claims.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. An integrated circuit (IC) package comprising:
a leadframe of a conductive material including a die attach pad and a lead finger separated from an edge of the die attach pad, wherein the leadframe has a first surface and a second surface opposite the first surface;
retaining features on the lead finger at the second surface;
a die on the first surface at the die attach pad; and
a molding compound that encapsulates the leadframe and the die and extends into and/or around the retaining features.

2. The IC package of claim 1, wherein the leadframe includes fabrication features on the second surface and the retaining features are arranged amongst the fabrication features.

3. The IC package of claim 2, wherein the retaining features include an arrangement of retaining features in the second surface.

4. The IC package of claim 3, wherein the fabrication features extend in a first direction, and the retaining features include spaced apart grooves that extend longitudinally along the lead finger at the second surface a second direction approximately perpendicular to the first direction.

5. The IC package of claim 1, wherein the lead finger has a T-shape.

6. The IC package of claim 1, wherein the retaining features are a first set of retaining features, and a second set of retaining features are formed on the second surface at the die attach pad.

7. The IC package of claim 3, wherein the retaining features include spaced apart voids that extend a depth from the second surface towards the first surface and the depth is less than or equal to approximately 40% of a thickness of the leadframe.

8. The IC package of claim 7, wherein at least one void of the voids has spaced apart sidewalls that are tapered in a direction extending from the second surface towards the first surface.

9. The IC package of claim 7, wherein at least one void of the voids has cross-sectional V-shape.

10. The IC package of claim 1, wherein:
the lead finger includes a plurality of lead fingers arranged around, coplanar with and spaced apart from a periphery of the die attach pad,
each of the lead fingers has respective retaining features formed along the second surface thereof, and
the molding compound extends into and/or around the respective retaining features.

11. A method of forming an integrated circuit (IC) comprising:
providing a leadframe of a conductive material including a lead finger and a die attach pad separated by a distance, wherein the leadframe has a first surface and a second surface opposite the first surface; and
forming retaining features in the second surface of the leadframe at the lead finger that are adapted to receive molding compound, wherein the retaining features are formed by adding and/or removing material with respect to the second surface.

12. The method of claim 11, wherein a top surface of the die includes a first bond pad, the lead finger defines a second bond pad at the first surface, the method further comprising:
coupling a bond wire between the first and second bond pads;
affixing the die to the first surface at the die attach pad; and
providing the molding compound to encapsulate the leadframe, the bond wire, and the die, in which the molding compound extends into and/or around the retaining features.

13. The method of claim 11, wherein the lead finger includes a plurality of lead fingers arranged around and spaced apart from the die attach pad, and forming the retaining features includes forming voids along the second surface of each of the respective lead fingers.

14. The method of claim 13, wherein forming the voids includes etching the second surface with a laser to form the voids.

15. The method of claim 13, wherein at least one void of the voids has spaced apart sidewalls that are tapered in a direction extending from the second surface.

16. The method of claim 11, wherein the leadframe includes fabrication features in the second surface extending in a first direction and the retaining features are amongst the fabrication features extending a second direction that is approximately perpendicular to the first direction.

17. The method of claim 11, wherein a spacing between adjacent pairs of the retaining features is approximately 25-40 microns.

18. The method of claim 11, wherein the leadframe has a leadframe thickness between the first surface and the second surface, and the retaining features extend a depth from the second surface towards the first surface that is less than or equal to approximately 40% of the leadframe thickness.

19. A device comprising:
a sheet of a conductive material having a first surface and a second surface opposite the first surface, wherein fabrication features extend in a first direction along at least one of the first and second surfaces, the sheet including:
a die attach pad; and
a plurality of lead fingers spaced apart from and surrounding the die attach pad, wherein an arrangement of retaining features is formed in at least one lead finger of the lead fingers extending along a second direction that is approximately perpendicular to the first direction.

20. The device of claim 19, wherein the sheet is a leadframe and the device further comprises:
a die affixed to the first surface at the die attach pad; and
a molding compound that encapsulates the leadframe and the die and extends into the retaining features of the arrangement of retaining features.

21. The device of claim 19, wherein the at least one lead finger has a T-shape, and the retaining features are grooves.

22. The device of claim 19, wherein the arrangement of retaining features includes voids formed on the second surface at the die attach pad.

23. The device of claim 22, wherein at least one void of the voids has spaced apart sidewalls that are tapered in a direction extending from the second surface.
